(19) United States
(12) Patent Application Publication
(10) Pub. No.: US 2026/0088775 A1
(43) Pub. Date: Mar. 26, 2026

(54) LINEAR AMPLIFYING DEVICE AND LINEAR AMPLIFYING METHOD THEREOF

(71) Applicant: REALTEK SEMICONDUCTOR CORP., Hsinchu (TW)

(72) Inventors: Kuan-Hao Tseng, Hsinchu (TW); Po-Chih Wang, Hsinchu (TW)

(73) Assignee: REALTEK SEMICONDUCTOR CORP., Hsinchu (TW)

(21) Appl. No.: 19/332,987

(22) Filed: Sep. 18, 2025

(30) Foreign Application Priority Data
Sep. 20, 2024 (TW) 113135846

(51) Int. Cl. H03F 1/32; H03F 3/16

(52) U.S. Cl. CPC H03F 1/32; H03F 3/16

(57) ABSTRACT

A linear amplifying device and a linear amplifying method are related to the linear amplifying device including an amplifying circuit, an attenuator, a linearizer, and a phase shifter. The attenuator, the linearizer and the phase shifter are connected in series and in order between an input terminal of the amplifying circuit and an output terminal of the amplifying circuit. The linear amplifying method includes receiving an input signal, generating an output signal according to the input signal and a gain, attenuating the output signal, generating a non-linear carrier wave in the attenuated output signal; adjusting a phase of the non-linear carrier wave to generate a feedback signal; and generating another output signal according to the input signal, the feedback signal, and the gain.

### CROSS-REFERENCE TO RELATED APPLICATION

This non-provisional application claims priority under 35 U.S.C. §119(a) to Patent Application No. 113135846 filed in Taiwan, R.O.C. on Sep. 20, 2024, the entire contents of which are hereby incorporated by reference.

### BACKGROUND

### Technical Field

The present disclosure relates to an amplifier, and in particular, to a linear amplifying device and a linear amplifying method thereof.

### Related Art

An amplifier is a semiconductor device, which is configured to amplify an input signal into an output signal. When a linear relationship exists between the input signal and the output signal, it means that the amplifier is a linear amplifier.

In the prior art, there are many kinds of circuits (called as linear amplifying circuits hereafter) that can implement linear amplifiers. However, the existing linear amplifying circuit still has some problems. For example, some linear amplifying circuits need excessive operations and adjustment mechanisms, causing an increase in the complexity, costs, and power consumption of the circuits, and therefore is not applicable to systems including a plurality of amplifiers (that is, multi-amplifier systems). In other words, the existing linear amplifying circuit can only be applied to a single amplifier. In addition, some other linear amplifying circuits need to calculate and adjust the input/output signal through an additional circuit or component, thereby improving linearity of the amplifier. However, the additional circuit and component significantly increases costs, a size, and power consumption of the amplifier.

### SUMMARY

In some embodiments, a linear amplifying device is provided, including an amplifying circuit, an attenuator, a linearizer, and a phase shifter. One terminal of the attenuator is electrically connected to an output terminal of the amplifying circuit. An input terminal of the linearizer is electrically connected to an other terminal of the attenuator. One terminal of the phase shifter is electrically connected to an output terminal of the linearizer, and an other terminal of the phase shifter is electrically connected to an input terminal of the amplifying circuit.

In some embodiments, the linear amplifying device further includes a capacitor. The capacitor is connected to the input terminal of the amplifying circuit.

In some embodiments, the amplifying circuit includes a capacitor.

In some embodiments, the attenuator is a capacitor with a fixed capacitance value.

In some embodiments, the attenuator is a variable capacitor.

In some embodiments, the linearizer is a transistor.

In some embodiments, the transistor is a metal-oxide-semiconductor field-effect transistor (MOSFET), and a gate-source voltage of the MOSFET is less than or equal to a threshold voltage of the MOSFET.

In some embodiments, the linearizer is a plurality of transistors connected in parallel with each other.

In some embodiments, the phase shifter is a resistor.

In some embodiments, the linear amplifying device further includes a resistor. One terminal of the resistor is electrically connected to an other terminal of the attenuator and the input terminal of the linearizer, and an other terminal of the resistor is electrically connected to a power supply.

In some embodiments, the linear amplifying device further includes a current source and a biasing device. The current source is electrically connected to a control terminal of the linearizer. One terminal of the biasing device is electrically connected to the control terminal of the linearizer, and an other terminal of the biasing device is grounded.

In some embodiments, the biasing device is a resistor.

In some embodiments, the biasing device is a transistor.

In some embodiments, the transistor is a diode-connected transistor.

In some embodiments, the current source is a proportional to absolute temperature (PTAT) circuit.

In some embodiments, the amplifying circuit is an amplifier.

In some embodiments, the amplifying circuit is a plurality of amplifiers connected in parallel with each other.

In some embodiments, the attenuator is a capacitor, the linearizer is a transistor, and the phase shifter is a resistor.

In some embodiments, a linear amplifying method is provided, including: receiving an input signal; generating an output signal according to the input signal and a gain; attenuating the output signal; generating a non-linear carrier wave in the attenuated output signal; adjusting a phase of the non-linear carrier wave to generate a feedback signal; and generating another output signal according to the input signal, the feedback signal, and the gain.

In some embodiments, a step of generating the non-linear carrier wave in the attenuated output signal further includes: controlling a linearizer by using a bias voltage.

Based on the above, according to any of the above embodiments, the linear amplifying device and the linear amplifying method can implement the linear amplifying circuit through a small number of components, and improve linearity of the linear amplifying circuit while reducing costs, a size, and power consumption of the linear amplifying circuit. In addition, the linear amplifying device and the linear amplifying method can generate a stable bias voltage through the current source and the biasing device to accurately control an operating state of the linearizer in the linear amplifying device, thereby improving stability of the linear amplifying circuit. Furthermore, the linear amplifying device is also applicable to a multi-amplifier system to implement a linearized multi-amplifier system.

### BRIEF DESCRIPTION OF THE DRAWINGS

FIG. 1 is a schematic circuit diagram of a linear amplifying device according to a first embodiment;

FIG. 2 is a schematic signal diagram of the linear amplifying device in FIG. 1;

FIG. 3 is a schematic diagram of operation of the linear amplifying device in FIG. 1;

FIG. 4 is a schematic circuit diagram of a first implementation of a linear amplifying device according to a second embodiment;

FIG. 5 is a schematic circuit diagram of a second implementation of a linear amplifying device according to a second embodiment;

FIG. 6 is a schematic circuit diagram of a linear amplifying device according to a third embodiment;

FIG. 7 is a schematic circuit diagram of a linear amplifying device according to a fourth embodiment;

FIG. 8 is a schematic circuit diagram of a current source and a biasing device according to the first embodiment;

FIG. 9 is a schematic circuit diagram of a current source and a biasing device according to the second embodiment;

FIG. 10 is a schematic circuit diagram of a linear amplifying device according to a fifth embodiment; and

FIG. 11 is a schematic circuit diagram of a linear amplifying device according to a sixth embodiment.

### DETAILED DESCRIPTION

In view of the terms used in this specification, it should be clear that the term “including” is an open term, and therefore should be interpreted as “including but not limited to”. The term such as “coupling” or “electrical connection” means that two or more components are in physical or electrical contact with each other “directly”, or in physical or electrical contact with each other indirectly. Terms “one”, “another”, “first”, “second”, and “third” are used to distinguish the referred components, and unless otherwise specified, are not used to order or limit the differences of the referred components, nor are they used to limit the scope of the present disclosure.

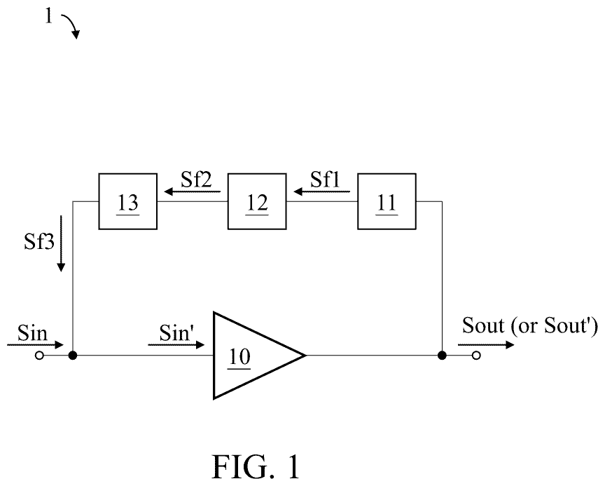

Refer to FIG. 1. A linear amplifying device 1 includes an amplifying circuit 10, an attenuator 11, a linearizer 12, and a phase shifter 13. The amplifying circuit 10 has an input terminal and an output terminal. One terminal of the attenuator 11 is electrically connected to the output terminal of the amplifying circuit 10, and an other terminal of the attenuator 11 is electrically connected to an input terminal of the linearizer 12. One terminal of the phase shifter 13 is electrically connected to an output terminal of the linearizer 12, and an other terminal of the phase shifter 13 is electrically connected to the input terminal of the amplifying circuit 10. In other words, the linearizer 12 is arranged between the attenuator 11 and the phase shifter 13.

In some embodiments, the amplifying circuit 10 is configured to amplify an input signal Sin/Sin′ into an output signal Sout/Sout′ based on a gain. With respect to the input signal Sin, the output signal Sout additionally includes a carrier wave with non-linear characteristics (also called as non-linear carrier waves WN, and the non-linear carrier waves WN included in the output signal Sout are called as first non-linear carrier waves WN1 hereafter). In some embodiments, the attenuator 11, the linearizer 12, and the phase shifter 13 constitute a feedback circuit, and the feedback circuit is configured to feed back the output signal Sout/Sout′ from the output terminal of the amplifying circuit 10 to the input terminal of the amplifying circuit 10.

In some embodiments, the attenuator 11 is configured to attenuate the output signal Sout, so that the first non-linear carrier waves WN1 of the output signal Sout is attenuated to a negligible amplitude, and then a feedback signal Sf1 is formed. In other words, the attenuator 11 is configured to attenuate the first non-linear carrier waves WN1 of the output signal Sout to generate the feedback signal Sf1. That is, the feedback signal Sf1 is generated through attenuating the amplitude of the first non-linear carrier waves WN1 of the output signal Sout into a negligible value.

In some embodiments, the linearizer 12 is configured to generate another non-linear carrier waves WN (called as second non-linear carrier waves WN2 hereafter) and output a feedback signal Sf2 according to the feedback signal Sf1 and the second non-linear carrier waves WN2. It should be noted that in some embodiments, quantities, frequencies, and phases of the first non-linear carrier wave WN1 of the output signal Sout and the second non-linear carrier wave WN2 of the feedback signal Sf2 are the same, but respective amplitudes thereof are different (for example, the amplitude of the first non-linear carrier wave WN1 is greater than the amplitude of the second non-linear carrier wave WN2).

In some embodiments, the phase shifter 13 is configured to adjust the phases of the second non-linear carrier waves WN2 and generate a feedback signal Sf3 according to the feedback signal Sf2 and the adjusted second non-linear carrier waves (called as third non-linear carrier waves WN3 hereafter). Quantities, frequencies, and amplitudes of the second non-linear carrier wave WN2 and the third non-linear carrier wave WN3 are the same, but phases thereof are different (for example, the phase of the second non-linear carrier wave WN2 is opposite to the phase of the third non-linear carrier wave WN3). Therefore, during amplifying of the signal by the amplifying circuit 10, the third non-linear carrier waves WN3 are used to eliminate the first non-linear carrier waves WN1, so that an output signal Sout′ does not include the first non-linear carrier waves WN1, thereby improving linearity of the amplifying circuit 10. In some embodiments, a ratio of the amplitude of the first non-linear carrier wave WN1 to the amplitude of the third non-linear carrier wave WN3 is related to the gain of the amplifying circuit 10. Specifically, a product of the amplitude of the third non-linear carrier wave WN3 and the gain of the amplifying circuit 10 is equal to the amplitude of the first non-linear carrier wave WN1. Herein, the amplified third non-linear carrier wave WN3′ can eliminate the first non-linear carrier wave WN1.

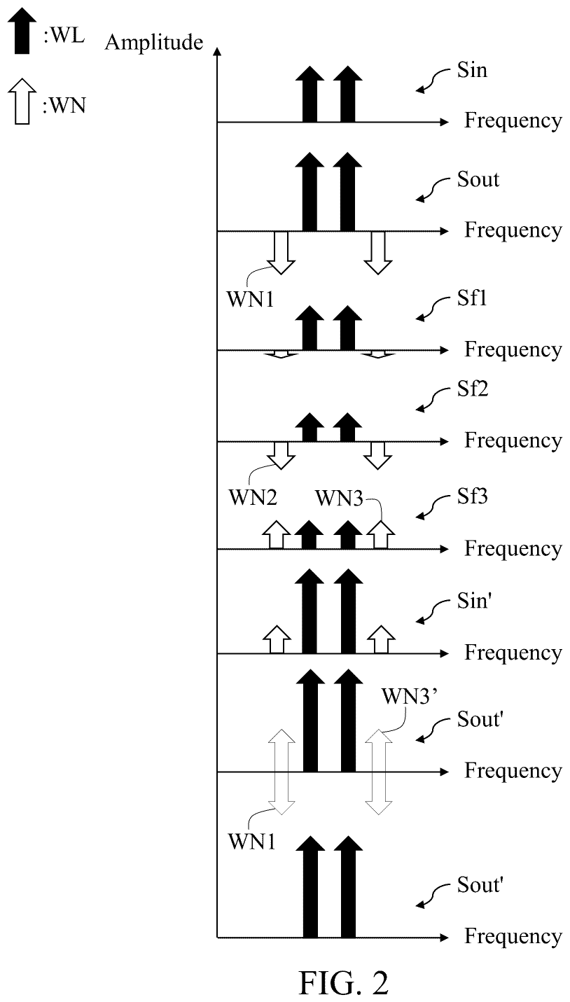

Referring to FIG. 1 to FIG. 3, when the linear amplifying device 1 is operated for the first time, the amplifying circuit 10 receives an input signal Sin from an external circuit (for example, a previous stage circuit of the linear amplifying device 1) through the input terminal of the amplifying circuit (corresponding to step S10), and the linear amplifying device 1 amplifies the input signal Sin into an output signal Sout based on the gain of the amplifying circuit 10 (corresponding to step S11). In some embodiments, the input signal Sin includes a plurality of carrier waves of different frequencies. FIG. 2 is used as an example. The input signal Sin includes two linear carrier waves WL. In other words, the input signal Sin shown in FIG. 2 is a two-tone signal.

In some embodiments, affected by internal components with non-linear characteristics in the amplifying circuit 10 (for example, a built-in transistor or capacitor of the amplifying circuit 10), the output signal Sout is distorted, resulting in an or more additional non-linear carrier waves WN. FIG. 2 is used as an example. The output signal Sout includes two linear carrier waves WL and two non-linear carrier waves WN (that is, the first non-linear carrier waves WN1), and the linear carrier wave WL and the non-linear carrier wave WN of the output signal Sout have different frequencies.

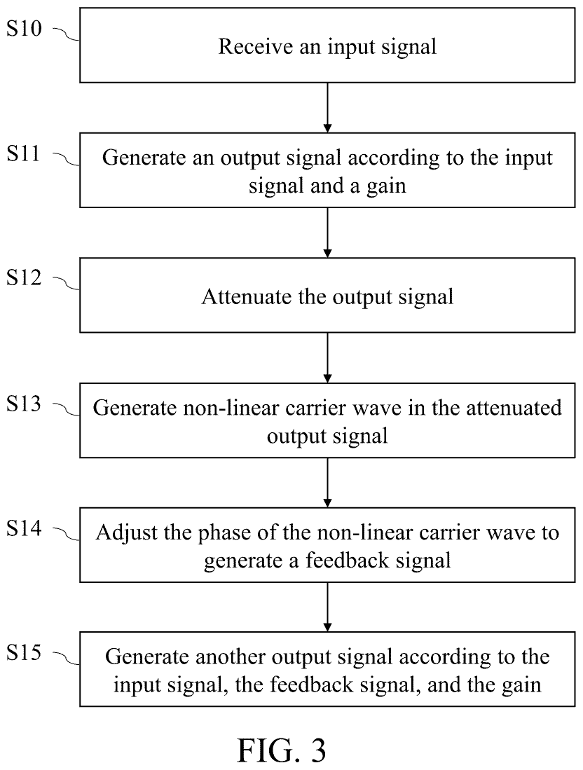

In some embodiments, the linear carrier wave WL and the first non-linear carrier wave WN1 of the output signal Sout are out of phase with each other (as shown in FIG. 3). In some other embodiments, the linear carrier wave WL and the first non-linear carrier wave WN1 of the output signal Sout are in phase with each other (not shown). The following description is provided by using an example in which the linear carrier wave WL and the first non-linear carrier wave WN1 are out of phase with each other.

After step S11, the linear amplifying device 1 attenuates the output signal Sout through the attenuator 11 to generate a feedback signal Sf1 (corresponding to step S12). In some embodiments, when the output signal Sout flows through the attenuator 11 in the feedback circuit, the attenuator 11 simultaneously attenuates the linear carrier waves WL and the non-linear carrier waves WN (that is, the first non-linear carrier waves WN1) of the output signal Sout, and the non-linear carrier waves WN of the output signal Sout are attenuated to a negligible amplitude.

After step S12, the linear amplifying device 1 adjusts the amplitude of the feedback signal Sf1 through the linearizer 12 to generate the feedback signal Sf2. In some embodiments, the linearizer 12 is configured to adjust the amplitude of the feedback signal Sf1 to adjust the gain of the amplifying circuit 10. FIG. 2 is used as an example. The linearizer 12 reduces the amplitude of the feedback signal Sf1 to generate a corresponding feedback signal Sf2, and the amplitude of the linear carrier wave WL of the feedback signal Sf2 is less than the amplitude of the linear carrier wave WL of the feedback signal Sf2. In addition, in some embodiments, affected by internal components with non-linear characteristics in the linearizer 12 (for example, a built-in transistor or capacitor of the linearizer 12), the feedback signal Sf1 is distorted, resulting in an or more additional non-linear carrier waves WN. In other words, after step S12, the linear amplifying device 1 generates the non-linear carrier wave(s) WN in the attenuated output signal Sout (that is, the feedback signal Sf1) (corresponding to step S13). Herein, the feedback signal Sf2 generated by the linearizer 12 includes one or more non-linear carrier waves WN (that is, second non-linear carrier waves WN2).

After step S13, the linear amplifying device 1 adjusts the phase of the non-linear carrier waves WN of the feedback signal Sf2 through the phase shifter 13 to generate the feedback signal Sf3 (corresponding to step S14). In some embodiments, when the feedback signal Sf2 flows through the phase shifter 13 in the feedback circuit, the phase shifter 13 adjusts the non-linear carrier waves WN (that is, the second non-linear carrier waves WN2) of the feedback signal Sf2 to be in phase with the linear carrier waves WL of the feedback signal Sf2. Herein, the linear carrier wave WL and the non-linear carrier wave WN (that is, the third non-linear carrier wave WN3) of the feedback signal Sf3 generated by the phase shifter 13 are in phase with each other (as shown in FIG. 2).

After step S14, the linear amplifying device 1 amplifies an input signal Sin′ including the feedback signal Sf3 into an output signal Sout′ through the amplifying circuit 10 (corresponding to step S15). In some embodiments, when the feedback signal Sf3 is fed back to the input terminal of the amplifying circuit 10, the amplifying circuit 10 receives the input signal Sin′ mixed by the input signal Sin and the feedback signal Sf3 and amplifies the input signal Sin′ into the output signal Sout′. Herein, when the amplifying circuit 10 amplifies the input signal Sin′, the non-linear carrier waves WN (that is, the third non-linear carrier waves WN3) of the feedback signal Sf3 are amplified into the amplified third non-linear carrier waves WN3′, and then the amplified third non-linear carrier waves WN3′ may eliminate the first non-linear carrier waves WN1 generated by the amplifying circuit 10, so that the output signal Sout′ is substantially an amplified signal formed by linearly amplifying the input signal Sin from an external circuit in a specific proportion.

FIG. 2 is used as an example. The non-linear carrier waves WN of the input signal Sin′ are the non-linear carrier waves WN (that is, the third non-linear carrier waves WN3) of the feedback signal Sf3. Herein, the non-linear carrier waves WN of the input signal Sin′ are amplified to cancel out the non-linear carrier waves WN caused by the amplifying circuit 10 in the output signal Sout′, so that the output signal Sout′ finally includes only the linear carrier waves WL. Herein, the linear amplifying device 1 may maintain a linear relationship between the input signal Sin and the output signal Sout′.

In some embodiments, the attenuator 11 may be a capacitor with a fixed capacitance value. In some other embodiments, the attenuator 11 may be a variable capacitor. Herein, the linear amplifying device 1 may adjust a degree of attenuation of the output signal Sout through the variable capacitor, thereby accurately eliminating the non-linear carrier waves WN of the output signal Sout′.

In some embodiments, the linearizer 12 may be a single transistor. In some other embodiments, the linearizer may be a plurality of transistors. The above transistor may be any type of bipolar junction transistor (BJT) or any type of metal-oxide-semiconductor field-effect transistor (MOSFET), but is not limited thereto.

In some embodiments, the linearizer 12 is a MOSFET, and a gate of the MOSFET receives a bias voltage having a fixed value. When the gate of the MOSFET receives the bias voltage, a gate-source voltage (Vgs) of the MOSFET is less than or equal to a threshold voltage (Vt) of the MOSFET. In other words, the linearizer 12 is implemented by using the MOSFET operating in a subthreshold region. Herein, in some embodiments of step S13, the linear amplifying device 1 controls an operation mode of the linearizer 12 using the bias voltage. The subthreshold region is well known to a person of ordinary skill in the art. Therefore, details are not described.

In some embodiments, the phase shifter 13 may be a single resistor. In some other embodiments, the phase shifter 13 may be an RC circuit including a resistor and a capacitor.

It should be clear that a user may autonomously adjust the components used in each unit (including the amplifying circuit 10, the attenuator 11, the linearizer 12, and the phase shifter 13) in the linear amplifying device 1 according to different usage conditions (for example, but not limited to cost constraints, size constraints, and power consumption constraints).

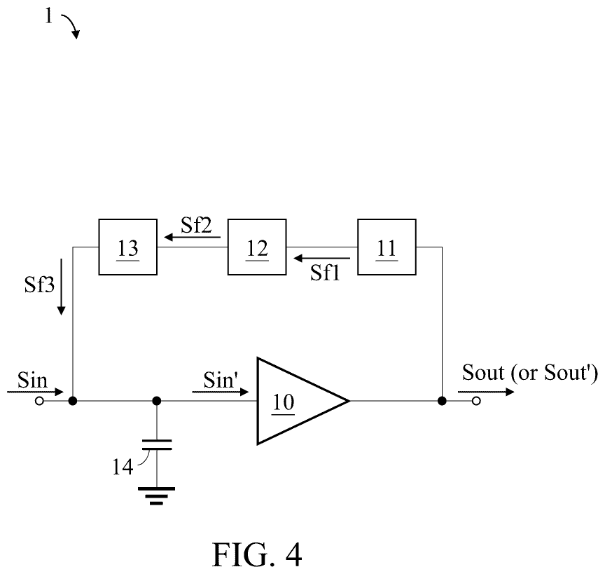

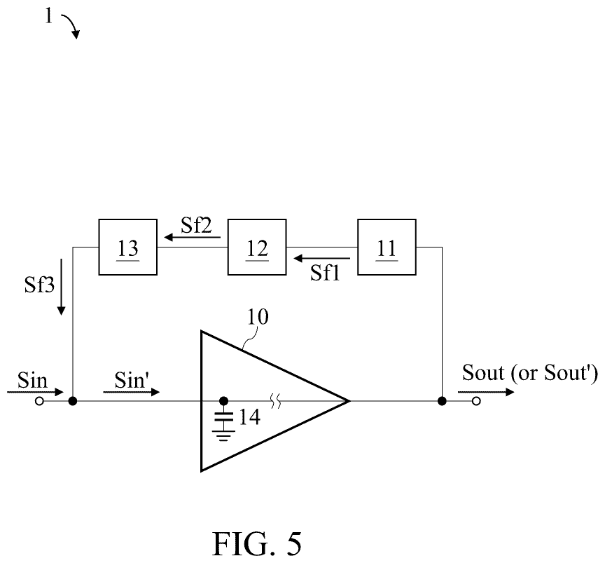

Refer to FIG. 4 and FIG. 5. In some embodiments, a linear amplifying device 1 further includes a capacitor 14, and the capacitor 14 is configured to interact with a phase shifter 13 to adjust a phase of a non-linear carrier wave WN of a feedback signal Sf2. In some embodiments, refer to FIG. 4. One terminal of the capacitor 14 is electrically connected to an input terminal of an amplifying circuit 10 and an other terminal of the phase shifter 13, and an other terminal of the capacitor 14 is grounded. In other words, the capacitor 14 is a component independently arranged outside the amplifying circuit 10, that is, the input terminal of the amplifying circuit 10 is externally connected to the capacitor 14, as shown in FIG. 4. In some other embodiments, refer to FIG. 5. The capacitor 14 may be arranged in the amplifying circuit 10. In other words, the capacitor 14 is a built-in component of the amplifying circuit 10 (as shown in FIG. 5), that is, the capacitor is one of the components constituting the amplifying circuit 10.

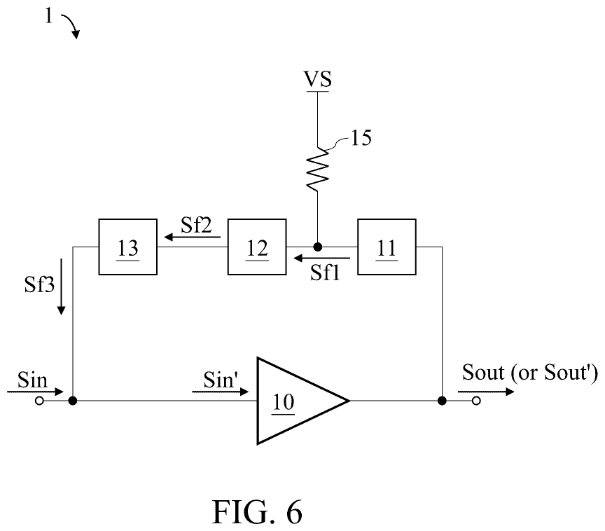

Refer to FIG. 6. In some embodiments, the linear amplifying device 1 further includes a resistor 15. One terminal of the resistor 15 is electrically connected between an other terminal of the attenuator 11 and the input terminal of the linearizer 12, and an other terminal of the resistor 15 is electrically connected to a power supply VS. In some embodiments, the resistor 15 is configured to superimpose the voltage provided by the power supply VS on the feedback signal Sf1, and then adjust the amplitude of the feedback signal Sf1 to adjust the gain of the amplifying circuit 10. Specifically, a cross-voltage between the input terminal of the linearizer 12 and the output terminal of the linearizer 12 affects the amplitude of the feedback signal Sf2 generated by the linearizer 12. Herein, the linear amplifying device 1 may further adjust a value of the cross-voltage through the resistor 15 to adjust the gain of the amplifying circuit 10. In some embodiments, the resistor 15 may be a variable resistor. Therefore, even if a voltage or current provided by the power supply VS is fixed, the linear amplifying device 1 may still adjust the voltage superimposed on the feedback signal Sf1 through the resistor 15.

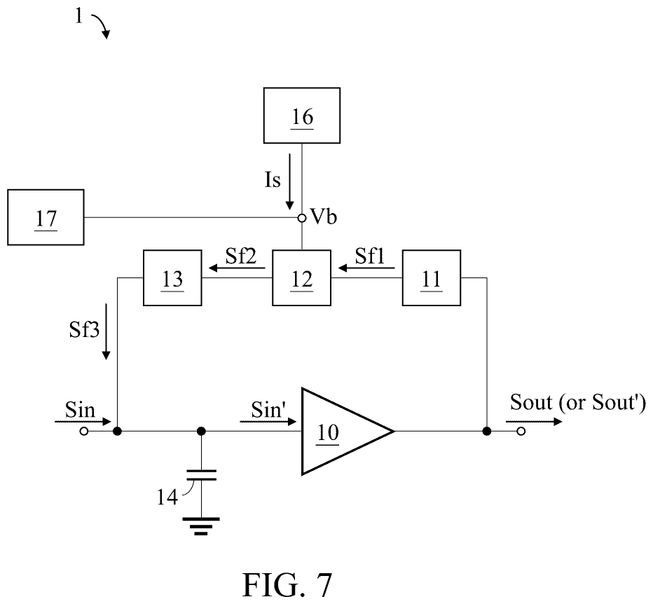

Refer to FIG. 7 to FIG. 9. As shown in FIG. 7, in some embodiments, a linear amplifying device 1 further includes a current source 16 and a biasing device 17. The current source 16 is electrically connected to a control terminal of a linearizer 12. One terminal of the biasing device 17 is electrically connected between the control terminal of the linearizer 12 and the current source 16, and an other terminal of the biasing device 17 is grounded. In other words, one terminal of the biasing device 17 and the current source 16 are jointly coupled to the control terminal of the linearizer 12. In some embodiments, the current source 16 is configured to generate a stable current Is, and the current Is flows into the biasing device 17 so that the biasing device 17 generates a stable bias voltage Vb at the control terminal of the linearizer 12, thereby applying the bias voltage Vb to the control terminal of the linearizer 12. Herein, the linear amplifying device 1 may accurately control an operating state of the linearizer 12 through the current source 16 and the biasing device 17.

For example, in some embodiments, when the linearizer 12 is a MOSFET, the MOSFET needs to operate in a subthreshold region to be used as the linearizer 12. Herein, the linear amplifying device 1 may accurately control the voltage applied to the control terminal of the linearizer 12 through the current source 16 and the biasing device 17, so that a voltage difference (corresponding to the gate-source voltage applied to the MOSFET) between the control terminal (corresponding to a gate terminal of the MOSFET) of the linearizer 12 and the output terminal (corresponding to a source terminal of the MOSFET) of the linearizer 12 is less than or equal to a threshold (corresponding to a threshold voltage of the MOSFET).

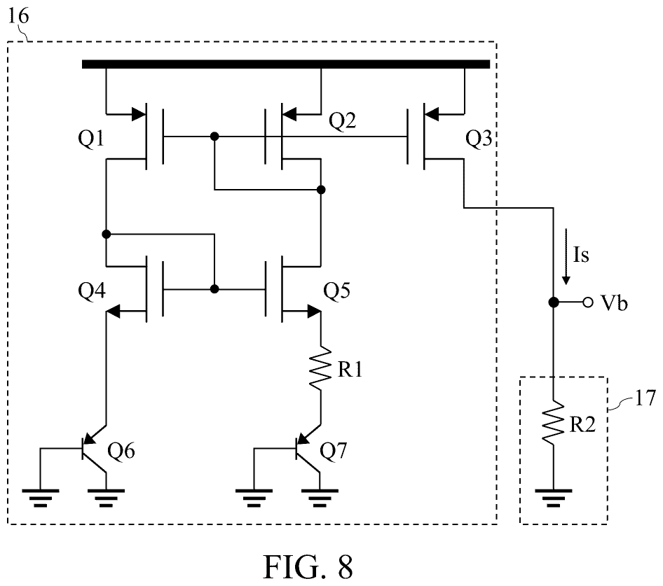

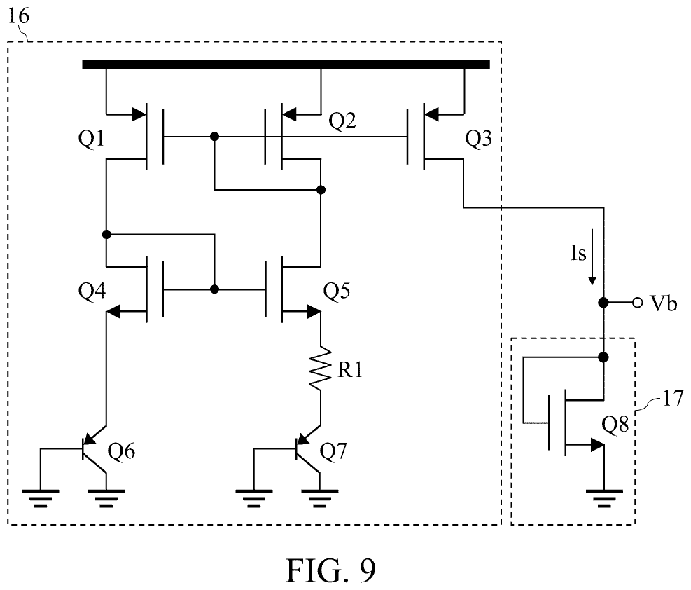

As shown in FIG. 8 and FIG. 9, in some embodiments, the current source 16 is a proportional to absolute temperature (PTAT) circuit. The PTAT circuit includes a plurality of MOSFETs Q1-Q5, a plurality of BJTs Q6-Q7, and a resistor R1. Herein, the linear amplifying device 1 may generate a stable current Is (also called as a PTAT current) through the PTAT circuit, and then generate a stable bias voltage Vb through the current Is and the biasing device 17 to control the operating state of the linearizer 12. The PTAT circuit is well known to a person of ordinary skill in the art. Therefore, details are not described.

In some embodiments, the biasing device 17 may be a resistor R2 (as shown in FIG. 8). In some other embodiments, the biasing device 17 may be a transistor Q8. The transistor Q8 is a diode-connected transistor, and the diode-connected transistor may be implemented by different types of transistors, for example, but not limited to the MOSFETs, the BJTs, or junction gate field-effect transistors (JFETs). FIG. 9 is used as an example. In this embodiment, the biasing device 17 is a diode-connected transistor implemented by the MOSFETs, and the diode-connected transistor may be used as a resistor for biasing. The diode-connected transistor is well known to a person of ordinary skill in the art. Therefore, details are not described.

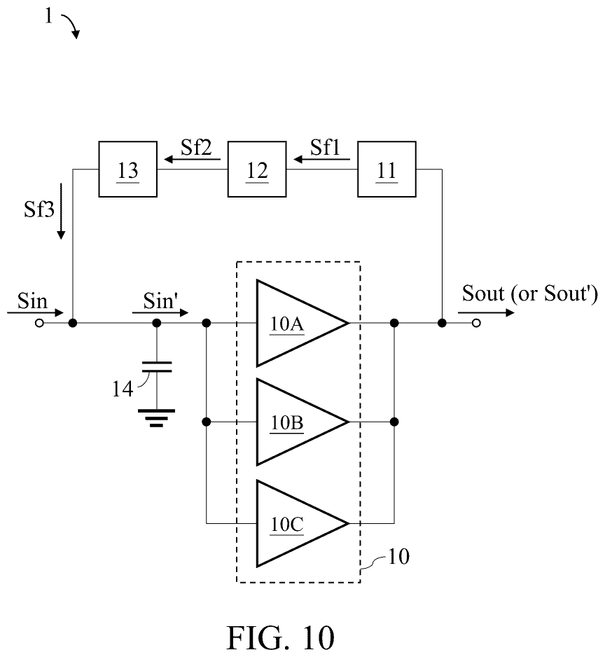

Refer to FIG. 1 and FIG. 10. In some embodiments, the amplifying circuit 10 may be a single amplifier (as shown in FIG. 1). In some other embodiments, the amplifying circuit 10 is a plurality of amplifiers. FIG. 10 is used as an example. In this embodiment, the linear amplifying device 1 includes three amplifiers 10A, 10B, and 10C, and the amplifiers 10A, 10B, and 10C are connected in parallel. In other words, an input terminal of the amplifier 10A, an input terminal of the amplifier 10B, and an input terminal of the amplifier 10C are electrically connected to each other, and an output terminal of the amplifier 10A, an output terminal of the amplifier 10B, and an output terminal of the amplifier 10C are electrically connected to each other. Herein, the attenuator 11, the linearizer 12, and the phase shifter 13 in the linear amplifying device 1 may simultaneously adjust linearity of each amplifier 10A/10B/10C, thereby implementing a linearized multi-amplifier system.

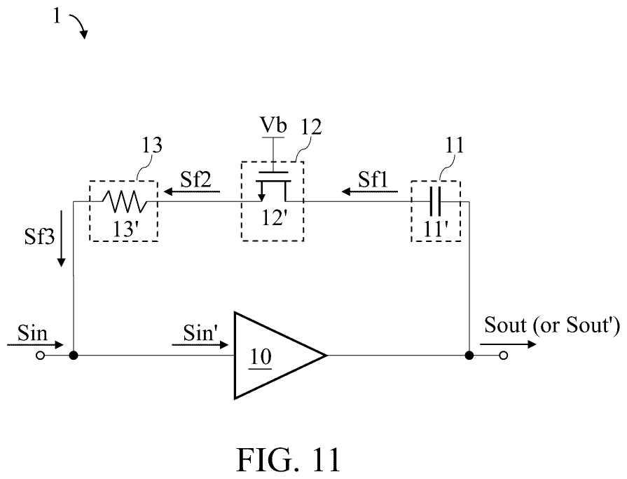

Refer to FIG. 11. In some embodiments, a linear amplifying device 1 simultaneously uses a capacitor 11′, a transistor 12′, and a resistor 13′ to serve as an attenuator 11, a linearizer 12, and a phase shifter 13 respectively. In other words, the linear amplifying device 1 may implement the attenuator 11, the linearizer 12, and the phase shifter 13 in the linear amplifying device 1 shown in FIG. 1 through a single electronic component, thereby reducing the costs, the size, and power consumption of the linear amplifying device 1.

In some embodiments, the amplifier may be any type of amplifying circuit, for example, but not limited to an electronic amplifier, a power amplifier, an operational amplifier, a transistor amplifier, a voltage amplifier, a current amplifier, a transconductance amplifier, and a transimpedance amplifier.

Based on the above, according to any of the above embodiments, the linear amplifying device and the linear amplifying method can implement the linear amplifying circuit through a small number of components, and improve linearity of the linear amplifying circuit while reducing costs, a size, and power consumption of the linear amplifying circuit. In addition, the linear amplifying device and the linear amplifying method can generate a stable bias voltage through the current source and the biasing device to accurately control an operating state of the linearizer in the linear amplifying circuit, thereby improving stability of the linear amplifying circuit. Furthermore, the linear amplifying device is also applicable to a multi-amplifier system to implement a linearized multi-amplifier system.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A linear amplifying device, comprising:
an amplifying circuit;
an attenuator, wherein one terminal of the attenuator is electrically connected to an output terminal of the amplifying circuit;
a linearizer, wherein an input terminal of the linearizer is electrically connected to an other terminal of the attenuator; and
a phase shifter, wherein one terminal of the phase shifter is electrically connected to an output terminal of the linearizer, and an other terminal of the phase shifter is electrically connected to an input terminal of the amplifying circuit.

2. The linear amplifying device according to claim 1, further comprising:
a capacitor, connected to the input terminal of the amplifying circuit.

3. The linear amplifying device according to claim 1, wherein the amplifying circuit comprises a capacitor.

4. The linear amplifying device according to claim 1, wherein the attenuator is a capacitor with a fixed capacitance value.

5. The linear amplifying device according to claim 1, wherein the attenuator is a variable capacitor.

6. The linear amplifying device according to claim 1, wherein the linearizer is a transistor.

7. The linear amplifying device according to claim 6, wherein the transistor is a metal-oxide-semiconductor field-effect transistor (MOSFET), and a gate-source voltage of the MOSFET is less than or equal to a threshold voltage of the MOSFET.

8. The linear amplifying device according to claim 1, wherein the linearizer is a plurality of transistors connected in parallel with each other.

9. The linear amplifying device according to claim 1, wherein the phase shifter is a resistor.

10. The linear amplifying device according to claim 1, further comprising:
a resistor, wherein one terminal of the resistor is electrically connected to an other terminal of the attenuator and the input terminal of the linearizer, and an other terminal of the resistor is electrically connected to a power supply.

11. The linear amplifying device according to claim 1, further comprising:
a current source, electrically connected to a control terminal of the linearizer; and
a biasing device, wherein one terminal of the biasing device is electrically connected to the control terminal of the linearizer, and an other terminal of the biasing device is grounded.

12. The linear amplifying device according to claim 11, wherein the biasing device is a resistor.

13. The linear amplifying device according to claim 11, wherein the biasing device is a transistor.

14. The linear amplifying device according to claim 13, wherein the transistor is a diode-connected transistor.

15. The linear amplifying device according to claim 11, wherein the current source is a proportional to absolute temperature (PTAT) circuit.

16. The linear amplifying device according to claim 1, wherein the amplifying circuit is an amplifier.

17. The linear amplifying device according to claim 1, wherein the amplifying circuit is a plurality of amplifiers connected in parallel with each other.

18. The linear amplifying device according to claim 1, wherein the attenuator is a capacitor, the linearizer is a transistor, and the phase shifter is a resistor.

19. A linear amplifying method, comprising:
receiving an input signal;
generating an output signal according to the input signal and a gain;
attenuating the output signal;
generating a non-linear carrier wave in the attenuated output signal;
adjusting a phase of the non-linear carrier wave to generate a feedback signal; and
generating another output signal according to the input signal, the feedback signal, and the gain.

20. The linear amplifying method according to claim 19, wherein a step of generating the non-linear carrier wave in the attenuated output signal further comprises:
controlling a linearizer by using a bias voltage.
